(19) United States
(12) Patent Application Publication
(10) Pub. No.: US 2025/0386442 A1
(43) Pub. Date: Dec. 18, 2025

(54) SUPPORT BRACKET FOR ELECTRICAL BOXES

(71) Applicant: ERICO International Corporation, Solon, OH (US)

(72) Inventors: Michael Hung Sun Oh, Twinsburg, OH (US); James Anthony Bukowski, Akron, OH (US)

(21) Appl. No.: 19/241,760

(22) Filed: Jun. 18, 2025

Related U.S. Application Data
(60) Provisional application No. 63/661,506, filed on Jun. 18, 2024.

(51) Int. Cl. H05K 5/02; H02G 3/12; H02G 3/36

(52) U.S. Cl. CPC H05K 5/0204; H02G 3/121; H02G 3/36

(57) ABSTRACT

Some aspects of the disclosure provide a support bracket to support an electrical system. The support bracket can include a first end flange that is securable to a first stud, a second end flange that is securable to a second stud that forms a stud cavity with the first stud, and a support profile that extends between the first and second end flanges and is configured to secure an electrical component. The first end flange and the second end flange each include bend features configured to be selectively bent to form a front-face configuration, a rear-face configuration, or a side face configuration. The first and second end flanges are securable to the first and second studs so that the support profile is aligned to support the electrical component with a front of the electrical component at a first offset rearward of the front faces of the first and second studs.

### CROSS-REFERENCE TO RELATED APPLICATIONS

This application claims priority to U.S. Provisional Patent Application No. 63/661,506, filed on Jun. 18, 2024, the entirety of which is incorporated by reference.

### BACKGROUND

Support brackets for electrical boxes can be used to mount electrical boxes to studs or other support structures.

### SUMMARY

Some embodiments of the disclosure provide a method of supporting an electrical system. The method can include providing a stud wall that can includes a first stud, a second stud, and drywall secured to front faces of the first and second studs; selectively bending first and second end flanges of a support bracket at first preformed bend lines on the first and second end flanges or at second preformed bend lines on the first and second end flanges; securing an electrical component to a support profile of the support bracket that can extend between the first and second end flanges; and after securing the electrical component to the support profile, securing the first and second end flanges to rear faces of the first and second studs so that the first and second end flanges extend along interior sides of the first and second studs to align the support profile to support the electrical component. The method can include aligning the support profile to support the electrical component at a first offset from the rear faces of the first and second studs, with the first and second end flanges bent at the first preformed bend lines, or include aligning the support profile to support the electrical component at a second offset from the rear faces of the first and second studs, with the first and second end flanges bent at the second preformed bend lines, the second offset being smaller than the first offset.

In some examples, the electrical component is secured at a front side of the support profile, where the first and second end flanges are bent rearward away from the front side of the support profile.

In some examples, the first and second end flanges can include third performed bend lines and fourth preformed bend lines. The third preformed bend lines can be configured to provide a side-face configuration to secure the support bracket to side walls of the first and second studs. The fourth preformed bend lines can be configured to provide a front-face configuration to secure the support bracket to the front faces of the first and second studs.

In some examples, the electrical component can include conductor support.

In some examples, the electrical component can include an electrical box.

The method of supporting an electrical system can further include selectively bending first and second end flanges of a second support bracket at first preformed bend lines on the first and second end flanges of the second support bracket or at second preformed bend lines on the first and second end flanges of the second support bracket; securing conductor support to a support profile of the second support bracket that extends between the first and second end flanges of the second support bracket; and after securing the conductor support to the support profile of the second support bracket, securing the first and second end flanges of the second support bracket to the rear faces of the first and second studs so that the conductor support is aligned above the electrical box. The method can include securing the first and second end flanges of the second support bracket to the rear faces of the first and second studs so that the conductor support is aligned above the electrical box at a third offset from the rear faces of the first and second studs, with the first and second end flanges of the second support bracket bent at the first preformed bend lines, or at a fourth offset from the rear faces of the first and second studs, with the first and second end flanges of the second support bracket bent at the second preformed bend lines, the fourth offset being smaller than the third offset.

In some examples, the third offset can be substantially equal to the first offset or the fourth offset can be substantially equal to the second offset.

In some examples, the method of supporting an electrical system can further include securing a mud ring to a front side of the electrical box with screws, where, with the first and second studs being 3⅝ inch studs, the first offset aligns the electrical box with the mud ring extending forward of a rear face of the drywall and with the screws flush with or rearward of the rear face of the drywall.

In some examples, the method of supporting an electrical system can further include securing a mud ring to a front side of the electrical box with screws, where, with the first and second studs being 2½ inch studs, the second offset aligns the electrical box with the mud ring extending forward of the rear face of the drywall and with the screws flush with or rearward of the rear face of the drywall.

Some embodiments of the disclosure provide a method of supporting an electrical system. The method can include providing a stud wall that includes a first stud and a second stud that form a stud cavity, each of the first stud and the second stud having a front face configured to secure drywall to the stud wall; selectively bending first and second end flanges of a support bracket at selective corresponding bend features to form one of a front-face configuration, a rear-face configuration, or a side-face configuration; securing an electrical component to a support profile of the support bracket that extends between the first and second end flanges; and after securing the electrical component to the support profile, securing the first and second end flanges to the first and second studs so that the support profile is aligned to support the electrical component. The method can include securing the first and second end flanges to the first and second studs so that the support profile is aligned to support the electrical component with a front of the electrical component at a first offset rearward of the front faces of the first and second studs, and, selectively, one of: the first and second end flanges secured in the front-face configuration to the front faces the first and second studs; the first and second end flanges secured in the rear-face configuration to rear faces of the first and second studs; or the first and second end flanges secured in the side-face configuration to side faces of the first and second studs.

In some examples, bending the first and second end flanges to form the front-face configuration can include bending free ends of the first and second end flanges outward relative to the stud cavity and bending the first and second end flanges to form the side-face configuration can include bending the free ends of the first and second end flanges inward relative to the stud cavity. In some examples, bending the first and second end flanges to form the front-face configuration can include bending the free ends outward at first bend features, and bending the first and second end flanges to form the side-face configuration can include bending the free ends inward at the first bend features. In some examples, with the first and second end flanges in the side-face configuration, securing the first and second end flanges to the first and second studs seats the first end flange on a front wall of the first stud that includes the front face of the first stud.

In some examples, each of the first end flange and the second end flange can include, in order, moving away from the support profile: a first bend feature, a second bend feature, a third bend feature, and selectively bending the first and second end flanges to the rear-face configuration includes selectively bending the first and second end flanges at one of: the first bend features, or the second bend features. In some examples, selectively bending the first and second end flanges to the front-face configuration can include bending the first and second end flanges at the third bend features. In some examples, selectively bending the first and second end flanges to the front-face configuration includes bending the first and second end flanges outwardly at the third bend features, and selectively bending the first and second end flanges to the side-face configuration includes bending the first and second end flanges inwardly at the third bend features. In some examples, each of the first end flange and the second end flange further includes a fourth bend feature, between the corresponding first bend feature and the support profile, and selectively bending the first and second end flanges to the rear-face configuration includes selectively bending the first and second end flanges to extend rearward at the fourth bend features and selectively bending the first and second end flanges to the front-face configuration includes bending the first and second end flanges to extend forward at the fourth bend features.

Some embodiments of the disclosure provide a support bracket to support an electrical system. The support bracket can include a first end flange that can be securable to a first stud, a second end flange securable to a second stud that forms a stud cavity with the first stud, and a support profile that can extend between the first and second end flanges and configured to secure an electrical component. Each of the first end flange and the second end flange can include, respectively, bend features that can be configured to be selectively bent to form any of a front-face configuration, a rear-face configuration, and a side-face configuration. The first and second end flanges can be securable to the first and second studs so that the support profile is aligned to support the electrical component with a front of the electrical component at a first offset rearward of the front faces of the first and second studs with, selectively, one of the first and second end flanges secured in the front-face configuration to the front faces the first and second studs, the first and second end flanges secured in the rear-face configuration to rear faces of the first and second studs, or the first and second end flanges secured in the side-face configuration to side faces of the first and second studs.

In some examples, the bend features for each of the first end flange and the second end flange can include one or more first bend features that define a first bend line and one or more second bend features that define a second bend line. The first and second end flanges can be bendable rearward relative to the stud cavity in the rear-face configuration so that the support profile supports the electrical component at the first offset rearward of the front faces of the first and second studs. The first and second end flanges can be selectively bendable: at the first bend lines to engage the rear faces of the first and second studs and extend along interior sides of the first and second studs, to align the support profile to support the electrical component at a first rear face offset from the rear faces of the first and second studs; and at the second bend lines to engage the rear faces of the first and second studs top extend along the interior sides of the first and second studs, to align the support profile to support the electrical component at a second rear face offset from the rear faces of the first and second studs.

In some examples, the bend features for each of the first end flange and the second end flange include one or more additional bend features that define one or more additional bend lines. The first and second end flanges can be selectively bendable at the one or more additional bend lines: forward relative to the stud cavity to the front-face configuration and the side face configuration; outwardly relative to the stud cavity to engage the front faces of the first and second studs in the front-face configuration; and inwardly relative to the stud cavity to engage the side faces of the first and second studs in the side-face configuration.

### BRIEF DESCRIPTION OF THE DRAWINGS

The accompanying drawings, which are incorporated in and form a part of this specification, illustrate examples of the disclosed technology and, together with the description, serve to explain the principles of examples of the disclosed technology:

FIG. 1 illustrates a support bracket, according to some aspects of the disclosure;

FIGS. 2A and 2B illustrate the support bracket of FIG. 1 in a first configuration and a second configuration, respectively, according to some aspects of the disclosure;

FIG. 3 illustrates the support bracket of FIG. 1 in a third, intermediate configuration, according to some aspects of the disclosure;

FIGS. 4A and 4B illustrate the support bracket of FIG. 1 in the first and second configurations, respectively, with a glider attachment;

FIGS. 5A and 5B illustrate the support bracket of FIG. 1 in the first configuration with an electrical box;

FIGS. 6A and 6B illustrate the support bracket of FIG. 1 in the second configuration with an electrical box;

FIGS. 7A and 7B illustrate the support bracket of FIG. 1 as configured in FIGS. 4A and 4B, respectively, with an electrical box;

FIG. 8 illustrates the support bracket of FIG. 1 as configured in FIGS. 5A and 5B, in an installed configuration;

FIG. 9 illustrates the support bracket of FIG. 1 as configured in FIGS. 6A and 6B, in an installed configuration;

FIGS. 10A-10C illustrate the support bracket of FIG. 1 as configured in FIG. 7A, in an installed configuration;

FIGS. 11A-11C illustrate the support bracket of FIG. 1 as configured in FIG. 7B, in an installed configuration;

FIG. 12A illustrates the support bracket of FIG. 1 in a fourth configuration, according to some aspects of disclosure;

FIG. 12B illustrates the support bracket of FIG. 1 as configured in FIG. 12A in an installed configuration;

FIG. 13A illustrates the support bracket of FIG. 1 in a fourth configuration, according to some aspects of disclosure;

FIG. 13B illustrates the support bracket of FIG. 1 as configured in FIG. 13A in an installed configuration;

FIG. 14A illustrates the support bracket of FIG. 1 in a fifth configuration with electrical supports, according to some aspects of disclosure;

FIG. 14B illustrates the support bracket of FIG. 1 as configured in FIG. 14A in an installed configuration;

FIG. 15A illustrates the support bracket of FIG. 1 in the fourth configuration with electrical supports, according to some aspects of disclosure;

FIG. 15B illustrates the support bracket of FIG. 1 as configured in FIG. 15A in an installed configuration;

FIG. 16A illustrates the support bracket of FIG. 1 in the first configuration with electrical supports, according to some aspects of disclosure; and

FIG. 16B illustrates the support bracket of FIG. 1 as configured in FIG. 16A in an installed configuration.

### DETAILED DESCRIPTION

Before any examples of the disclosed technology are explained in detail, it is to be understood that the disclosure is not limited in its application to the details of construction and the arrangement of components set forth in the following description or illustrated in the following drawings. The disclosure is capable of other examples and of being practiced or of being carried out in various ways.

The following discussion is presented to enable a person skilled in the art to make and use examples of the disclosed technology. Various modifications to the illustrated examples will be readily apparent to those skilled in the art, and the generic principles herein can be applied to other examples and applications without departing from the disclosed technology. Thus, the disclosed technology is not intended to be limited to examples shown, but are to be accorded the widest scope consistent with the principles and features disclosed herein. The following detailed description is to be read with reference to the figures, in which like elements in different figures have like reference numerals. The figures, which are not necessarily to scale, depict selected examples and are not intended to limit the scope of disclosed technology. Skilled artisans will recognize the examples provided herein have many useful alternatives and fall within the scope of the disclosed technology.

In various installation, electrical components or other equipment (e.g., electrical outlets, switches, or other devices, etc.) can be installed onto walls. In particular, electrical components can include electrical boxes (e.g., junction boxes, other enclosures to support or enclose electrical devices) or electrical supports (e.g., first means of support for cable or other wiring systems extending from an electrical box, or other structures to support conduit, cables, boxes, etc.) that are configured to be installed to stud walls, including prefabricated stud walls.

Some prefabricated stud walls can be wall modules that provide a prefabricated portion of a larger wall and can include two studs that define a stud cavity therebetween, and a layer of drywall or other wall covering attached to a front face of the two studs. In some instances, the wall module can be prefabricated to include a cut out for electrical components (e.g., to receive a mud ring of a junction box assembly). In some instances, such a cut out can be added to a wall module at time of installation or otherwise (e.g., after an electrical assembly is installed).

Conventional installation of electrical components onto wall modules can be relatively difficult, particularly during prefabrication operations (e.g., to prefabricate stud walls at locations remotely located—e.g., off-site-relative to a building location at which the stud walls will be used). For instance, if a wall module already includes a wall covering (e.g., drywall) on front faces of the studs of the wall module, it may not be practical to mount electrical components to the front faces of the studs.

Further, in an installed configuration, it is generally important for the installed electrical components (e.g., an electrical junction box assembly, electrical supports) to be reliably secured at an appropriate depth relative to the wall covering. For example, mud rings of junction boxes may be required to be positioned flush with a front surface of a wall covering or with a relatively small rearward offset relative to the front surface of the wall covering. Issues may also arise if front features of the electrical component (e.g., screws to secure a mud ring) are pressed into a rear surface of a wall covering. For example, such an arrangement can put unwanted pressure on a drywall section and may lead to cracks or other damage to the drywall during transportation or installation.

Some examples of the disclosed technology can address these or other issues. For example, some configurations include a support bracket that is readily adjustable to support electrical assemblies (e.g., electrical boxes with attached mud rings, corresponding electrical supports, etc.) on prefabricated wall modules (or otherwise). In particular, the support bracket can have various configurations to allow users to selectively locate assemblies of different sizes with appropriate spacing relative to wall modules of different dimensions. For example, some support brackets according to the disclosure can locate electrical assemblies of various sizes with appropriate rearward offsets within wall modules having various stud depths. In some examples, a support bracket for electrical components can include end flanges that may be selectively bendable at pre-formed bend features to be attached to a rear surface of the studs of prefabricated stud walls. In some examples, the end flanges may also be selectively bent in an opposite direction (e.g., at other pre-formed bend features) to be attached to a front surface of the studs of the wall module. In some examples, the end flanges may also be selectively bent at pre-formed bend features to be attached to a side surface of the studs of the wall module.

In particular, to install electrical components to prefabricated stud walls in some examples, end flanges of a support bracket may be bent to provide offsets corresponding to different depths of the wall studs of a wall module, including with selective bending at one or more bend lines on each end flange to place the support bracket in any of a front-face configuration, a rear-face configuration, or a side-face configuration. Further, in some cases, selectively bending the end flanges to any of the noted configurations can include selectively bending the end flanges to provide different offset distances in the different configurations (e.g., different offsets from a rear or front face of the relevant studs in any of the front-face configuration, the rear-face configuration, or the side-face configuration). Thus, some examples of the disclosed technology can allow installed electrical components to be appropriately aligned with a back or a front surface of drywall, as applicable (e.g., to be flush with the relevant surface, or to include an appropriately small rearward offset therefrom). For example, some examples can ensure that a front of an electrical box or mud ring is offset no more than 0.25 (e.g., 24) inches rearward of a finished surface of a wall covering (e.g., drywall), including with offsets of less than 0.1 inches in some cases (e.g., offsets of less than 0.07 inches).

In some examples, a mud ring may be secured to a front side of the electrical component (e.g., electrical box) with screws. With the support bracket bent at selected bend features to support the front of the electrical component with a rearward offset from the front faces studs, the mud ring can be supported so that a front of the mud ring is flush with or slightly offset rearward from a front surface of drywall or other wall covering that is secured to the front faces of the studs of the wall module. Additionally, the heads of the screws that secure the mud ring to the electrical box may be either flush with the back surface of the drywall or rearwardly offset to provide a small gap between the screws and the back surface of the drywall.

In some examples, a support bracket for electrical components can provide a support profile for electrical boxes, such as junction boxes or other enclosures to support or enclose electrical devices. In other examples, the support bracket for electrical components can provide a support profile for electrical supports, such as conduits, cables, boxes, or the like. In such examples, the support bracket can provide a conductor support (e.g., a first means of support) for the electrical supports.

As used herein, the term “first means of support” (FMOS) refers a first point of support of electrical components that extend from an electrical box. For example, within a run of an electrical component (e.g., a conduit or cable), certain building codes require electrical components to be secured along a length of the run within a particular distance of an electrical box from which the run extends.

In some examples, a support bracket may accordingly be used to support a conduit clip, cable clip, or other support device known in the art as a FMOS for an associated electrical box (or other component). In particular, using examples of the support bracket disclosed herein, such a support device can be easily aligned with an electrical box within a stud cavity to provide a FMOS for cable, conduit, or other components that extend from an electrical box. In some examples, this approach can allow effectively automatic alignment of a FMOS with an electrical box, particularly during manufacture of a pre-fabricated stud wall.

In some examples, an electrical component (e.g., an electrical junction box) may be directly secured to the support bracket, e.g., with screws. In other examples, the electrical component may be mounted to a slidable bracket, generally referred to herein as a glider, for adjustable location laterally along the support bracket.

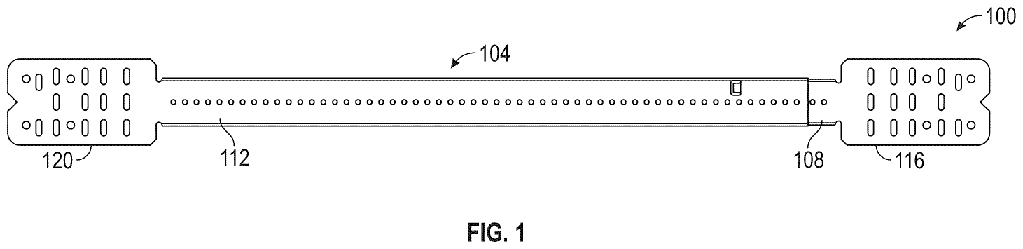

In some examples, support brackets can be adjustable-length (e.g., telescoping) support brackets, although fixed-length or other adjustable brackets are also possible. In particular, in the example illustrated in FIG. 1, a support bracket 100 can include a first support member 108 and a second support member 112. In the illustrated example, the first support member 108 and the second support member 112 are slidably nested to provide a support profile 104 with adjustable length in a lateral direction (e.g., left-to-right from the perspective of FIG. 1). In some embodiments, the first support member 108 and second support member 112 can include features that allow the support profile 104 to telescopically extend or retract to pre-defined lengths. For instance, one of more of the support members 108, 112 may include a protrusion that connects with a corresponding aperture or other protrusion at particular lengths of the support profile 104, which may allow the support bracket 100 to be slidably extended or retracted to a desired length.

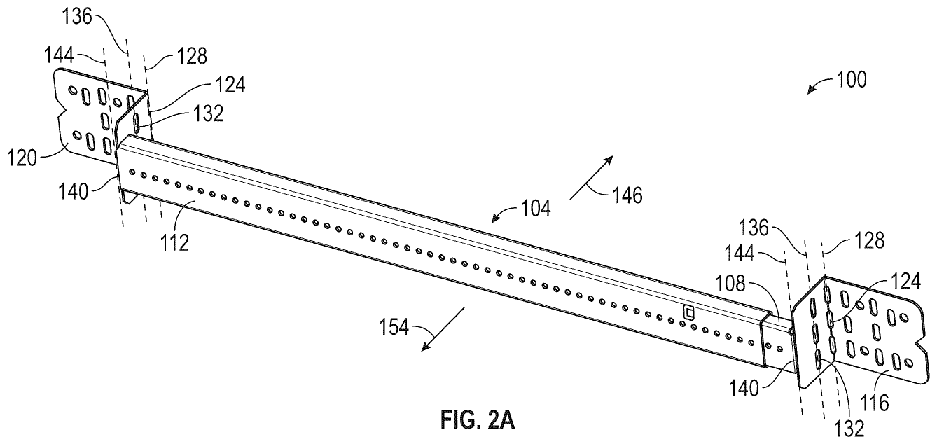

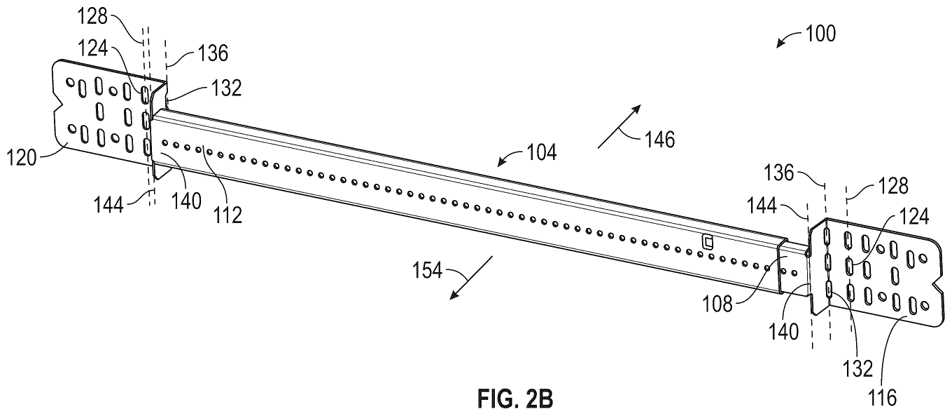

In the example illustrated, the first support member 108 includes a first end flange 116. Similarly, the second support member 112 includes a second end flange 120. Referring in particular to FIGS. 2A and 2B, the first and second end flanges 116, 120 can include one or more (preformed) bend features 124 that define corresponding bend lines 128. Additionally, in some embodiments, the first and second end flanges 116, 120 can include one or more (preformed) bend features 132 that define corresponding bend lines 136. As shown in FIGS. 2A and 2B, the one or more bend features 124 and one or more bend features 132 can include elongate cut-outs on the first and second end flanges 116, 120, which extend along the corresponding bend lines 128, 136. In other embodiments, the one or more bend features 124, 132 can include a continuous score line, a discontinuous score line (e.g., a dashed score line or the like), a differently configured cut-out, or an otherwise weakened portion of the corresponding flange that can define a bend line for manual (or other) adjustment.

In some embodiments, the one or more bend lines 128, 136 may advantageously allow the first and second end flanges 116, 120 to be secured at rear faces of studs (e.g., a first stud and a second stud of a wall module). Thus secured, the flanges 116, 120 can extend forward along (laterally) interior sides of the studs to align the support profile 104 to selectively support an electrical component at different offsets from a rear face of a stud.

For example, the one or more bend lines 128 may allow the first and second end flanges 116, 120 to be easily placed in a rear-face configuration to engage with rear faces of first and second studs to align the support profile 104 at a first offset from the rear faces of the studs, as discussed in greater detail below. In a preferred embodiment, the first offset may be configured to align the support profile 104 to support an electrical junction box on first and second studs that have a 3⅝ inch depth (i.e., on standard 3⅝″ studs), with the bracket configured as shown in FIG. 2A and secured to back faces of the studs.

Similarly, a second (different) offset from the rear face of the studs can be defined by the one or more bend lines 136. For example, as illustrated in FIG. 2B, the first and second end flanges 116, 120 are bent at the one or more bend lines 136 to provide a rear-face configuration with a second offset that is smaller than the first offset. In a preferred embodiment, the second offset may be configured to align the support profile 104 to support an electrical junction box on first and second studs that have a 2½ inch depth (i.e., on standard 2½″ studs), with the bracket configured as shown in FIG. 2B and secured to back faces of the studs.

In some embodiments, each the first and second end flanges 116, 120 may include more than two bend features, including as may allow the flanges 116, 120 to be easily bent to provide other installation configurations (e.g., side-face and front-face configurations, as further discussed below). As such, each of the first and second end flanges 116, 120 may include more than two bend lines, corresponding to more than two offsets. For example, as shown in FIGS. 1-3, the first end flange 116 and second end flange 120 each include one or more additional preformed bend features 140 that each define one or more additional bend lines 144 at opposed lateral ends of the support profile 104 (e.g., at a transition between nesting sliding profiles of the support members 108, 112 and the corresponding flanges 116, 120).

In some installations, the first and second end flanges 116, 120 can be bent along the one or more bend lines 144 in a direction 146 (e.g., first direction, rear direction) relative to a support profile. For example, as shown in FIGS. 2A and 2B, the first and second end flanges 116, 120 are bent to extend rearwardly at the bend lines 144, relative to a front face of the support profile 104, to extend in a direction substantially parallel to direction 146. In other words, the flanges 116, 120 are bent away from a front side of the support profile 104, to extend toward (and past) a rear side of the support profile 104. This configuration, as further discussed below, can allow the end flanges 116, 120 to attach to the rear faces of the relevant studs to provide corresponding offsets therefrom (e.g., based on selective second-direction bends at either of the sets of bend lines 128, 136, as also discussed above). In some embodiments, the first and second flanges 116, 120 are bent in the direction 146 to extend at 90 degrees (or about 90 degrees) relative to the support profile 104, with corresponding 90 degree (or about 90 degree) bends at the relevant bend line(s) 128, 136.

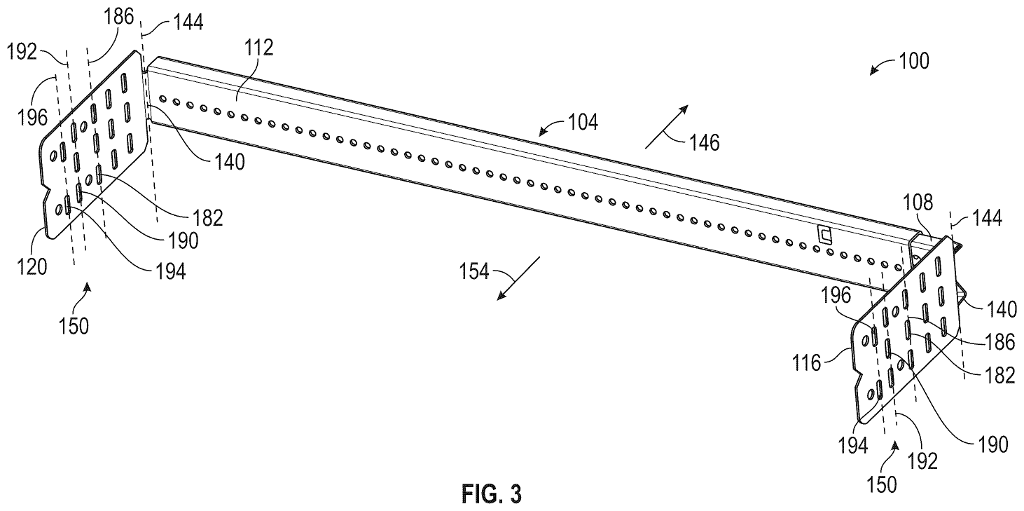

In other installations, the first flange 116 and second flange 120 can be bent along the one or more bend lines 144 to extend in a direction 154 (e.g., second direction, forward direction), opposite the direction 146. For example, as shown in FIG. 3, the first and second end flanges 116, 120 are bent forwardly along at the bend lines 144, relative to the front face of the support profile 104 (e.g., to extend substantially parallel to a direction 154). This illustrated intermediate configuration can allow the end flanges 116, 120 to attach to the front faces of the relevant studs (e.g., for on-site installation before installing drywall). For example, in different installations, free ends of the first and second flanges 116, 120 can also be bent outwardly relative to the support profile 104 and the corresponding stud cavity (see below) at one or more additional bend lines 150 (e.g., each formed by respective cut-outs or other bend features). This combination of bends can selectively align the support profile 104 to support an electrical box or other component at corresponding offsets from the front of the studs, with free ends of the flanges 116, 120 seated on front faces of the studs (as further discussed below).

In some installations, the first and second flanges 116, 120 are bent forward to extend at 90 degrees (or about 90 degrees) relative to the support profile 104, with corresponding 90 degree (or about 90 degree) bends at the relevant bend line(s) 144, 150 (e.g., to extend substantially parallel to the direction 154). Similarly free ends of the flanges 116, 120 can be bent outwardly (or inwardly, in some cases) to extend at about 90 degrees relative to a remainder of the flanges 116, 120, with corresponding about 90 degree bends at the relevant bend line(s) 150 (e.g., to extend substantially perpendicular to the direction 154).

For example, bend lines 150 may include bend lines 186, preformed bend lines 192, and preformed bend lines 196 that correspond with preformed bend features 182, bend features 190, and bend features 194, respectively. As discussed in further detail below, the bend lines 186, 192, 196 on each first and second flanges 116, 120 may allow the support bracket 100 to be installed in front- and side-face configurations.

In some installations, the direction 146 may be substantially orthogonal to and extend away from a front surface of the support profile 104. In other installations, the direction 146 may be perpendicular to the front surface of the support profile 104. In some installations, the direction 146 may be non-parallel to the front surface of the support profile 104. In some installations, the direction 154 may be parallel (or substantially parallel) to the direction 146, but extend in a direction opposite to the direction 146. In some installations, the direction 154 may be substantially orthogonal to the front surface of the support profile 104.

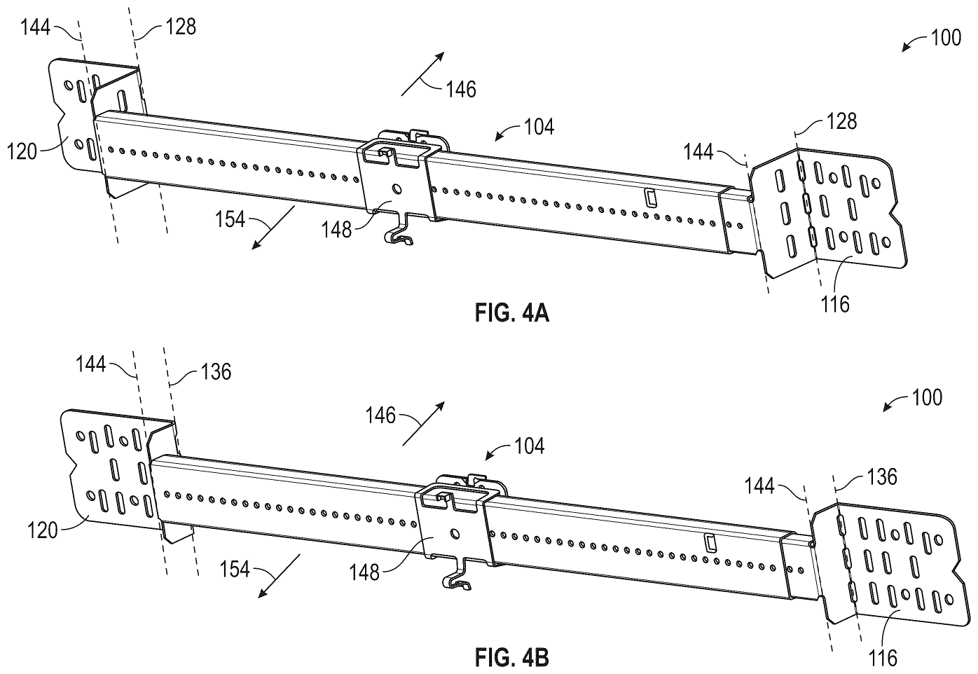

In different installations, an electrical component (e.g., electrical box, electrical support) can be attached directly to a support profile (e.g., with threaded fasteners) or can be attached to a support profile with a distinct attachment device. For example, to provide lateral adjustability of a location of an electrical component between a first and second stud (e.g., because a corresponding cutout in the wall cover has not yet been formed), it may be advantageous to secure a slidable glider attachment to the support profile to secure the electrical component. For example, as shown in FIGS. 4A and 4B, the support bracket 100 can support a slidable bracket configured as a glider 148. The inclusion of the glider 148 generally allows for an electrical component to be slid laterally along the support profile 104 to align the electrical component at a desired location (e.g., in alignment with an aperture in a wall cover of a wall module).

In some installations, as shown in FIG. 4A, the glider 148 can be included on the support bracket 100, with the first and second end flanges 116, 120 bent in the direction 146 along the bend lines 144 and bent in the direction 154 at the bend lines 128. In some installations, as shown in FIG. 4B, the glider 148 can be included on the support bracket 100, with the first and second end flanges 116, 120 bent in the direction 146 along the bend lines 144 and further bent at the bend lines 136.

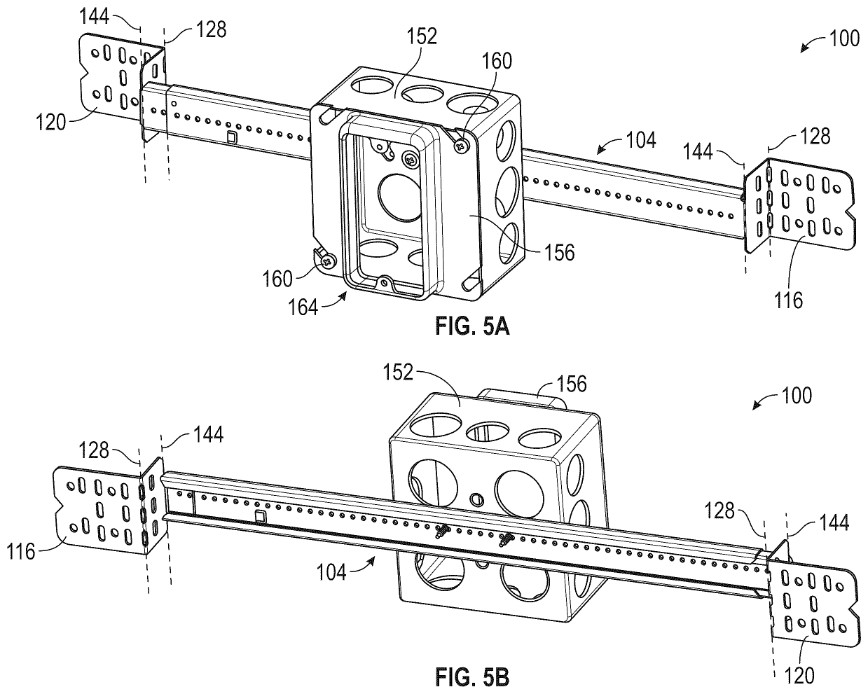

In some aspects of the disclosure, an electrical component (e.g., electrical box, electrical support) may be secured to a support profile of a support bracket. In some installations, the electrical component may also include a mud ring that is configured to extend through an aperture in a wall covering of a wall module. For example, as depicted in FIGS. 5A and 5B, a back side of an electrical box 152 is secured to a front side of the support profile 104, and a mud ring 156 is secured to a front side of the electrical box 152. In some examples, the electrical box 152 is directly secured to the support profile 104 using screws or other fasteners (e.g., self-drilling screws, as shown in FIGS. 5A and 5B).

As also discussed below, with the mud ring 156 secured to the electrical box 152 with fasteners 160, the first and second end flanges 116, 120 may be bent to an installation configuration to support the electrical box 152 so that a small gap is provided between a frontmost surface of the fastener 160 (e.g., a surface of the fastener farthest from the support profile 104) and a rear surface of drywall of a prefabricated stud wall (or other wall covering). In some installations, however, the frontmost face of the fastener 160 can be supported flush with the rear surface of the drywall (or other wall covering) or in other desired orientations.

In some installations, including as shown in FIGS. 5A and 5B, the first and second end flanges 116, 120 can be bent at the bend lines 128 to be aligned to support the electrical box 152 and the mud ring 156, with the electrical box 152 being 2⅛ inches deep and the mud ring 156 being ¾ inches deep (or ⅝ inches deep, in some cases). Generally, a variety of box and mud ring widths are possible, including with standard 4 inch box and 4 11/16 inch box configurations.

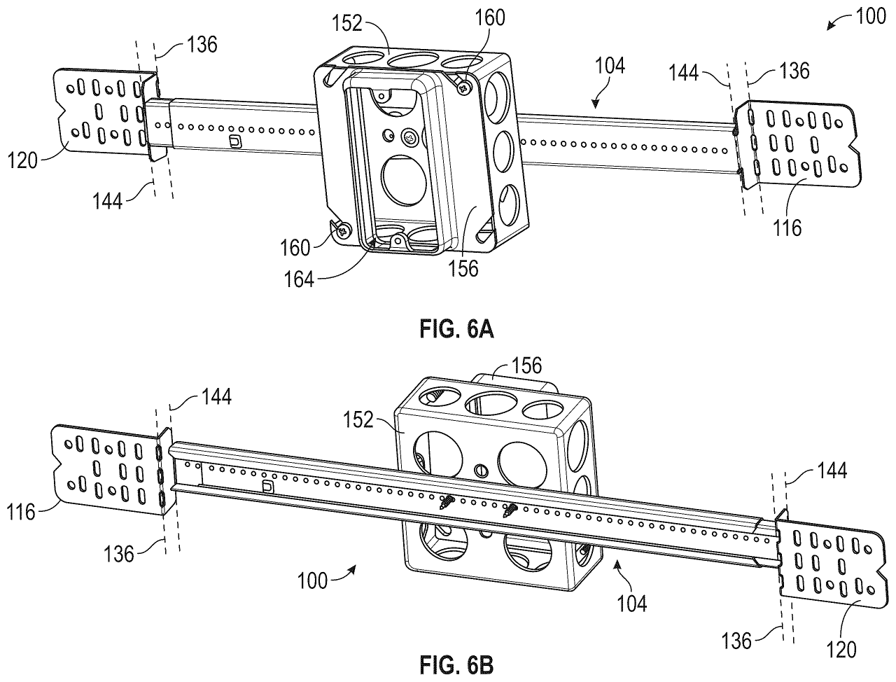

In some installations, including as shown in FIGS. 6A and 6B, the first and second end flanges 116, 120 can be bent at the bend lines 136 to be aligned to support the electrical box 152 and the mud ring 156, with the electrical box 152 being 1½ inches deep and the mud ring 156 being ¾ inches deep (or ⅝ inches deep, in some cases).

As shown in the examples of FIGS. 5A and 6A, the mud ring 156 can include a single aperture 164 that can accommodate a single electrical device (i.e., can be a single gang mud ring). In other installations, a mud ring can support multiple electrical devices (e.g., as a double gang mud ring).

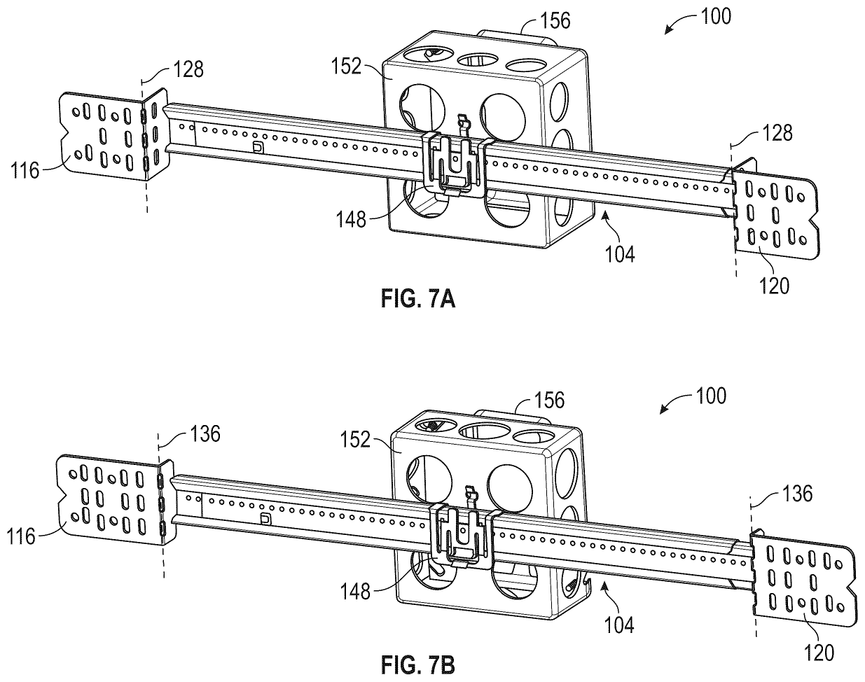

In some installations, as also noted above, an electrical component (e.g., an electrical box with a mud ring) may be secured with a slidable (or other) bracket. For example, as shown in FIGS. 7A and 7B, the electrical box 152 can be installed on the glider 148, with the glider 148 attached to the support profile 104. In some installations, with the first and second end flanges 116, 120 bent at the bend lines 128, the support profile 104 can be aligned for appropriate support for the electrical box 152 and the mud ring 156, when the electrical box 152 has a 2⅛ inch depth and the mud ring 156 has a ¾-inch depth (or a ⅝-inch depth, in some cases).

In some installations, when the electrical box 152 and mud ring 156 are secured to the glider 148, the first and second end flanges 116, 120 can be bent at the bend lines 136. Accordingly, the support profile 104 can be aligned for appropriate support for the electrical box 152 and the mud ring 156, when the electrical box 152 has a 1½ inch depth and for the mud ring 156 has with a ¾-inch depth (or a ⅝-inch depth, in some cases).

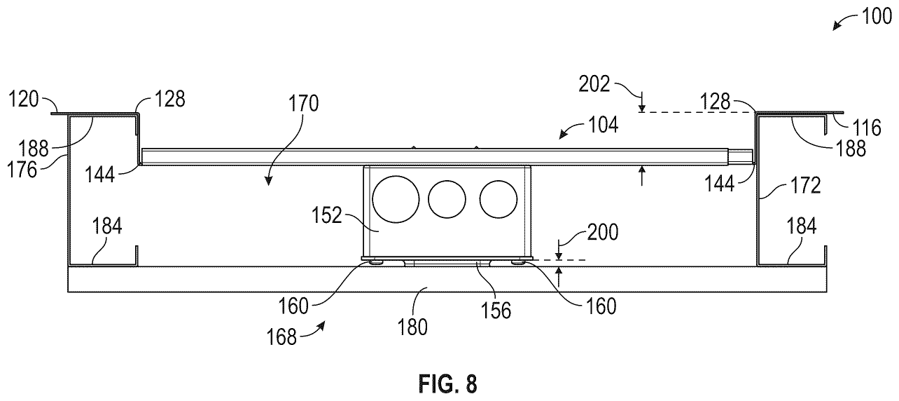

In some installations, a support bracket with a support profile, an electrical box secured to the support profile, and a mud ring secured to the electrical box can be mounted to a first stud and a second stud. For example, as shown in FIG. 8, the support bracket 100 is secured to a prefabricated stud wall 168, with the electrical box 152 secured to the support profile 104, and the mud ring 156 secured to the electrical box 152. The prefabricated stud wall 168 includes a first stud 172, a second stud 176, and drywall 180. The first and second studs 172, 176 each include a front face 184 and a rear face 188, and the drywall 180 is secured to the front faces 184.

In some installations, the first wall stud 172 and the second wall stud 176 form a corresponding stud cavity 170. Generally, the stud cavity 170 can be defined as a space confined between the studs 172, 176. In particular, the stud cavity 170 can be defined as a space between the wall studs 172, 176 and behind the drywall 180.

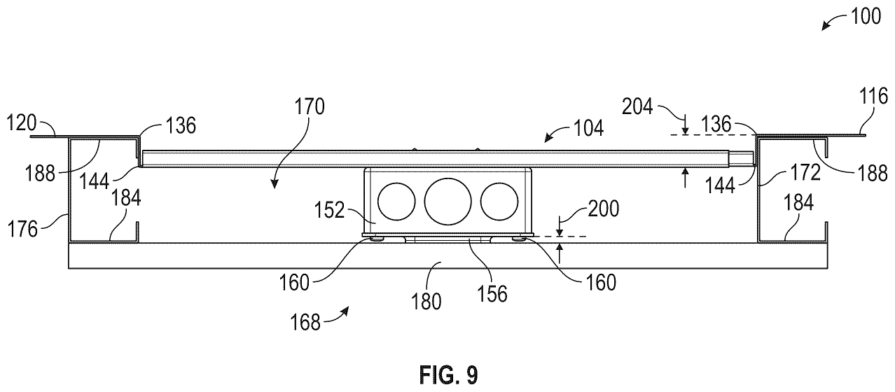

In the example installation depicted in FIG. 8, the first end flange 116 is mounted to the rear face 188 of the first stud 172 and the second end flange 120 is mounted to the rear face 188 of the second stud 176. Further, the first stud 172 and second stud 176 are 3⅝ inch studs and the electrical box 152 is a 2⅛ inch electrical box. Correspondingly, the bracket 100 can be bent at the bend lines 128, 144 to appropriately align the electrical box 152 and the mud ring 156 relative to the studs 172, 176 and the drywall 180. In particular, with the support bracket 100 in the illustrated rear-face configuration, the bend lines 128, 144 can be oriented on the end flanges 116, 120 so that the support profile 104 is aligned to support the front of the electrical box 152 (or another electrical component) at a predetermined offset 200 rearward of the front faces 184 (see also FIGS. 9, 10B, 11B for other configurations of the bracket 100). Correspondingly, the electrical box 152 can be supported with sufficient clearance behind the drywall 180 that components secured to the front of the electrical box 152 do not adversely interfere with the drywall 180. For example, at least a 0.020 inch gap may be provided between a frontmost surface the fastener 160 and a rear surface of the drywall 180 (e.g., with the drywall 180 flush with the front faces 184 of the studs 172, 176).

In other words, the first flange 116 of the support member 108 may be installed on the rear face 188 of the first stud 172 and the second member 120 of the support bracket 112 may be installed on the rear face 188 of the second stud 176, leaving a gap between the electrical box 152 (or other component) and the drywall 180 (e.g., a gap of substantially equal size as the rearward offset 200). Specifically, the flange 116 may be bent at bend lines 144 via bend features 140 so that the flange 116 extends to the rear side of the support profile 104 (e.g., parallel to direction 146), and the flange 116 may be further bent at bend lines 128 via bend features 124 so that the flange 116 extends outwardly away from the stud cavity 170 and is secured to the rear face 188 of the stud 172. Similarly, the flange 120 may be bent at bend lines 144 via bend features 140 so that the flange 120 extends to the rear side of the support profile 104 (e.g., parallel to direction 146), and the flange 120 may be further bent at bend lines 128 via bend features 124 so that the flange 120 extends outwardly away from the stud cavity 170 and is secured to the rear face 188 of the stud 176. Correspondingly, the flanges 116, 120 are bent outwardly relatively to the stud cavity 170 so that the free ends of the flanges 116, 120 (e.g., ends of the flanges past the bend features 124) extend outwardly relative to the stud cavity 170.

In other installations, as shown in FIG. 9, the first stud 172 and second stud 176 are 2½ inch studs and the electrical box 152 is a 1½ inch electrical box. Correspondingly, the end flanges 116, 120 can be mounted to the rear faces 188 of studs 172, 176, with the end flanges 116, 120 bent at the bend lines 136, 144 to provide a smaller offset forward from the rear faces 188 of the studs 172, 176 than in the example of FIG. 8 (e.g., as shown by offsets 202, 204 of FIGS. 8 and 9). Thus, as similarly discussed above, at least a 0.020 inch gap may be provided between a frontmost surface of the fastener 160 and a rear surface of the drywall 180 (e.g., with the drywall flush with the front faces 184 of the studs 172, 176).

In other words, similar to FIG. 8, the first flange 116 of the support member 108 in FIG. 9 may be installed on the rear face 188 of the first stud 172 and the second flange 120 of the support member 112 may be installed on the rear face 188 of the second stud 176, leaving a gap between the electrical box 152 (or other component) and the drywall 180 (e.g., a gap of substantially equal size as the rearward offset 200). Specifically, the flange 116 may be bent at bend lines 144 via bend features 140 so that the flange 116 extends to the rear side of the support profile 104 (e.g., parallel to direction 146), and the flange 120 may be bent at bend lines 144 via bend features 140 so that the flange 120 extends to the rear side of the support profile 104 (e.g., parallel to direction 146). However, different from FIG. 8, the flange 116 may be further bent at bend lines 128 via bend features 124 so that the flange 116 extends outwardly away from the stud cavity 170 and is secured to the rear face 188 of the stud 172. Similarly, the flange 120 may be further bent at bend lines 128 via bend features 124 so that the flange 120 extends outwardly away from the stud cavity 170 and is secured to the rear face 188 of the stud 176. Thus, the flanges 116, 120 are bent outwardly relatively to the stud cavity 170 so that the free ends of the flanges 116, 120 (e.g., ends of the flanges past the bend features 132) extend outwardly relative to the stud cavity 170.

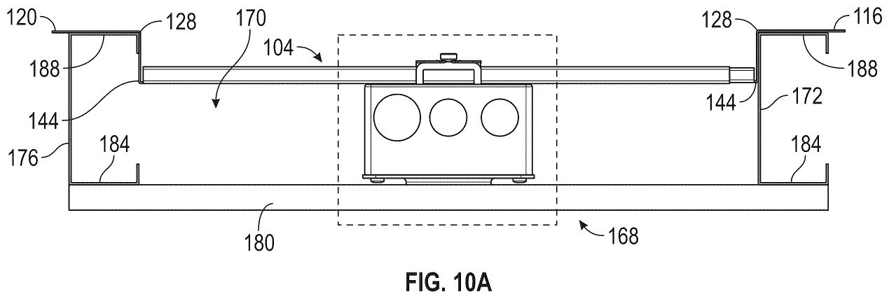

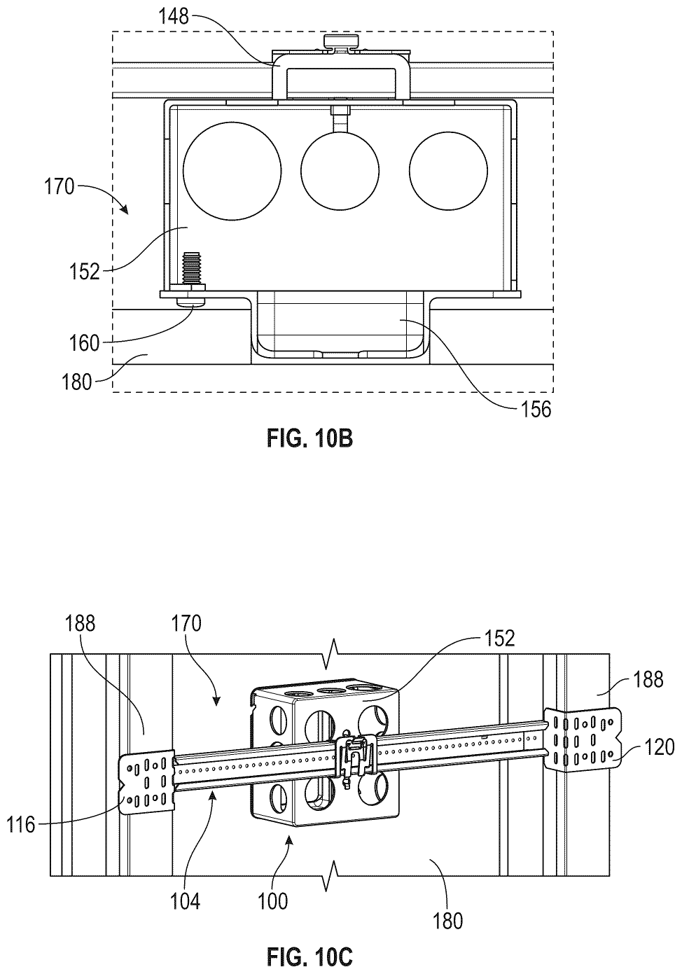

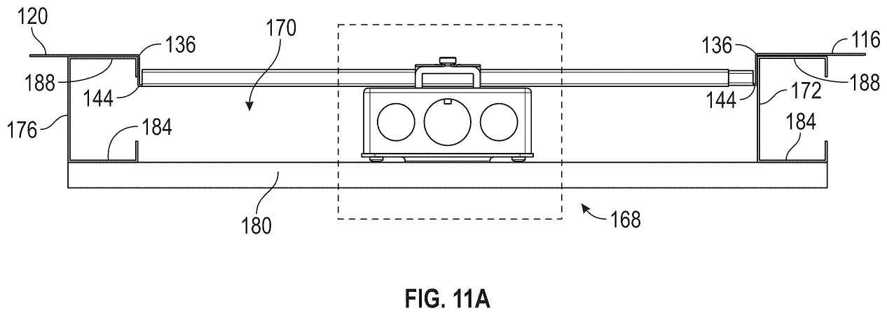

Support of a directly-attached electrical component with a gap or a flush alignment between a mud ring screw and a wall covering can help to ensure that the mud ring screws (or other similar components) do not penetrate or otherwise damage the wall covering when the electrical component is attached with a glider. For example, as shown in FIGS. 10A-10C, the support bracket 100 is mounted to the prefabricated stud wall 168, with the glider 148 securing the electrical component 152 to the support profile 104.

In particular, the first and second studs 172, 176 as depicted in FIGS. 10A-10C are 3⅝ inch studs and the electrical box 152 is a 2⅛ inch electrical box. Correspondingly, the first and second end flanges 116, 120 are bent at the bend lines 128, 144 to support the assembly with a frontmost face of the fasteners 160 flush with the rear surface of the drywall 180. In some installations, however, the fasteners 160 can be thus supported to be offset rearwardly from the rear surface of the drywall 180 (e.g., with a smaller gap than in the configuration of FIG. 8).

Similarly, for a ⅝-inch thickness of the drywall 180, a frontmost face of the mud ring 156 may be flush with a front surface of the drywall 180 or may be offset rearwardly therefrom by a relatively small gap. For example, for the configuration shown in FIG. 10B, the mud ring 156 can be ¾ inches deep and a gap between the front surface of the drywall 180 and the frontmost face of the mud ring 156 may be about 0.070 inches (or less). Or the mud ring 156 can be ⅝ inches deep, and the gap may about 0.19 inches (or less).

Correspondingly, in a similar installation without the glider 148 (e.g., as shown in FIG. 8), the support bracket 100 can support the mud ring 156 to be rearwardly offset from the front surface of the drywall 180 by a somewhat larger gap. For example, a gap of about 0.090 inches (or less) can be provided for a ¾-inch mud ring, a gap of about 0.21 inches (or less) can be provided for a ⅝-inch mud ring, or a gap of less than 0.24 inches may be provided in general.

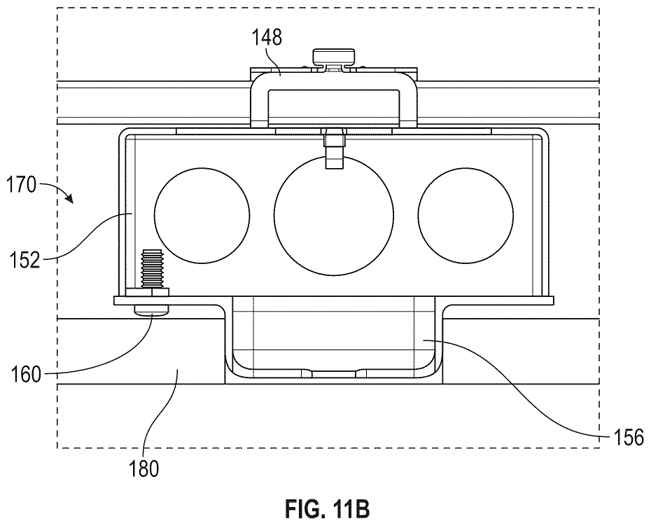

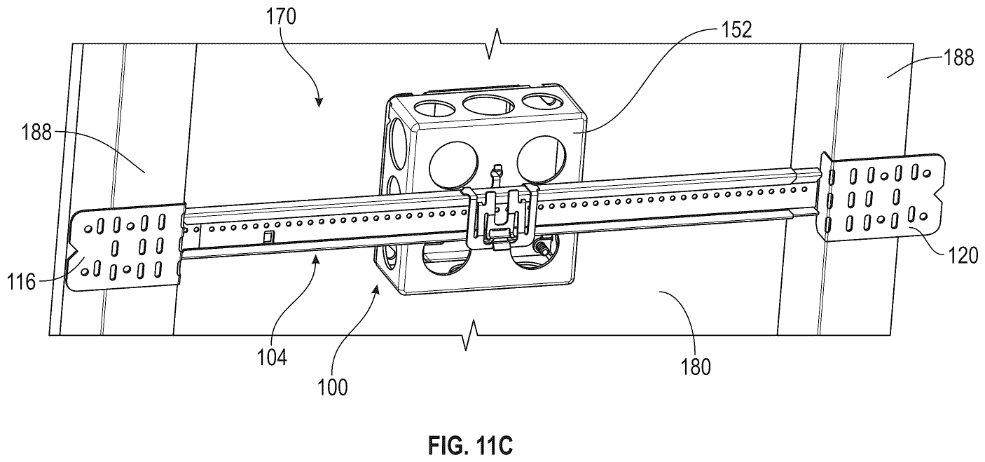

Similar alignment can also be provided when the first and second studs 172, 176 are 2½ inch studs. For example, with the first and second end flanges 116, 120 bent at the bend lines 136, 144 and the electrical box 152 as a 1½ inch box, as illustrated in FIGS. 11A-11C, a frontmost face of the fasteners 160 may be offset from the rear surface of the drywall 180 by a gap or may be flush with the rear surface of the drywall 180. Correspondingly, as shown in FIG. 9 and also generally discussed above, at least a 0.020 inch gap may be provided between a frontmost surface of the fastener 160 and a rear surface of the drywall 180 when the glider 148 is not used.

Similarly, for a ⅝ inch thickness of the drywall 180, as depicted in FIG. 11B, a frontmost face of the mud ring 156 secured to the electrical box 152 may be spaced rearwardly from a front surface of the drywall 180 by a gap of about 0.070 inches (or less) for a ¾-inch mud ring, or by a gap of about 0.21 inches (or less) for a ⅝-inch mud ring. Correspondingly, in a similar installation without the glider 148 (e.g., as shown in FIG. 9), the support bracket 100 can support the mud ring 156 to be rearwardly offset from the front surface of the drywall 180 by a gap of about 0.090 inches (or less) for a ¾-inch mud ring, by a gap of about 0.21 inches (or less) for a ⅝-inch mud ring, or generally by a gap of less than 0.24 inches.

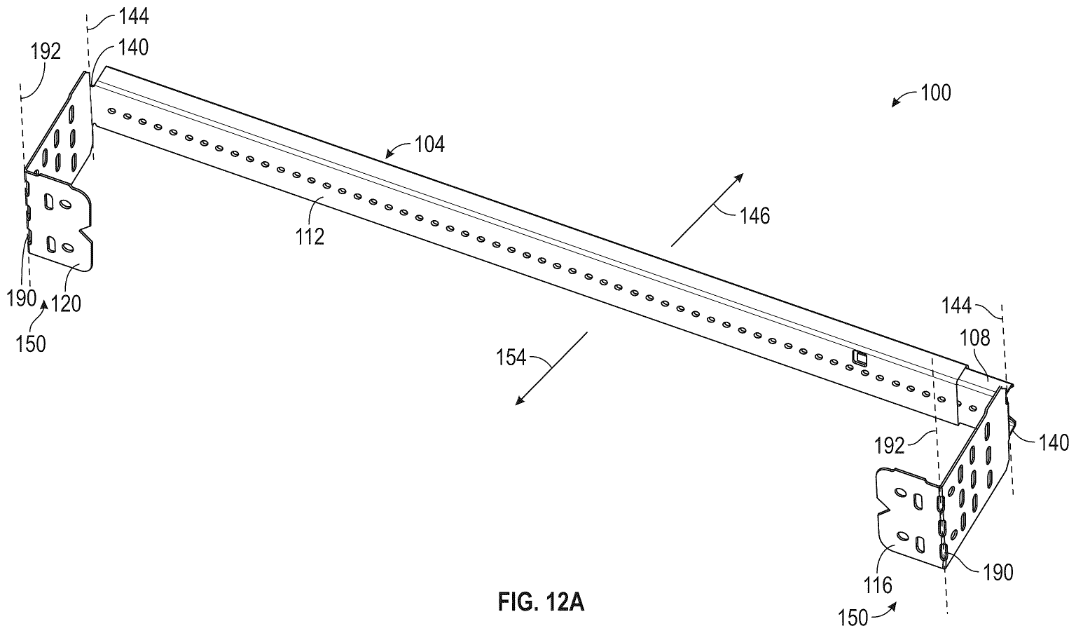

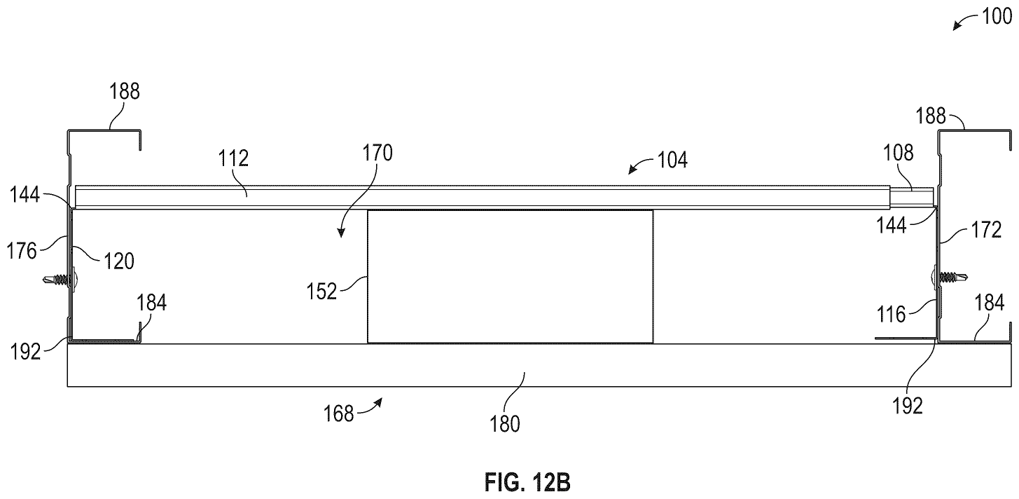

As discussed above, a support bracket may be installed in a side installation in addition to the rear installation. For example, a support bracket may be configured so that end flanges are bend at bend features and bend lines into a side-face configuration, so that the support bracket can be installed along a side face extending along an inside side wall of a stud that faces toward the relevant stud cavity. In particular, as shown in FIG. 12A and FIG. 12B, the flanges 116, 120 may bend at the bend lines 144 via the bend features 140 so that the flanges 116, 120 extend along a direction substantially parallel to direction 154 (see also FIG. 3).

Further, to be accommodated within the stud cavity 170, the flanges 116, 120 may be further bent along bend lines 192 via bend features 190 in a direction substantially perpendicular to direction 154 (see also FIG. 3). In other words, as shown in FIG. 12B, the flanges 116, 120 may be bent inwardly relatively to the stud cavity 170 so that the free ends of the flanges 116, 120 (e.g., ends of the flanges past the bend features 190) extend inwardly into the stud cavity 170. As shown in FIG. 12B, the free end of the flange 120 can be seated on rear side of the front wall of the stud 176 to help easily align the support bracket 100 for service. Thus, a distance between the bend features 140 and the bend features 190 may determine a distance from the support profile 104 and the drywall 180 of the prefabricated stud wall 168.

As shown in FIG. 12B, the first flange 116 is installed on a side face of the first stud 172 and the second flange 120 is installed on a side face of the second stud 176. In some installations, as shown in FIG. 12B, the second flange 120 may be installed on the second stud 176 so that the second flange 120 is secured within an interior cavity of the stud 176 defined between the front face 184, and rear face 188. In other installations, the first flange 116 may be installed on the first stud 172 so that the first flange 116 is secured within a cavity of the stud defined by the first stud 172, the front face 184, and rear face 188. In other words, the bracket 100 can be reversibly installed so that the first flange 116 may be installed on the second stud 176 and the second flange 120 may be installed on the first stud 172, or the first flange 116 may be installed on the first stud 172 and the second flange 120 may be installed on the second stud 176.

As shown schematically in FIG. 12B, the electrical box 152 of FIG. 5A can be installed with the support bracket 100 in the side-face configuration shown in FIGS. 12A and 12B. Similarly, the electrical box 152 can be secured to the glider 148 and installed with the support bracket 100 in the side-face configuration shown in FIGS. 12A and 12B.

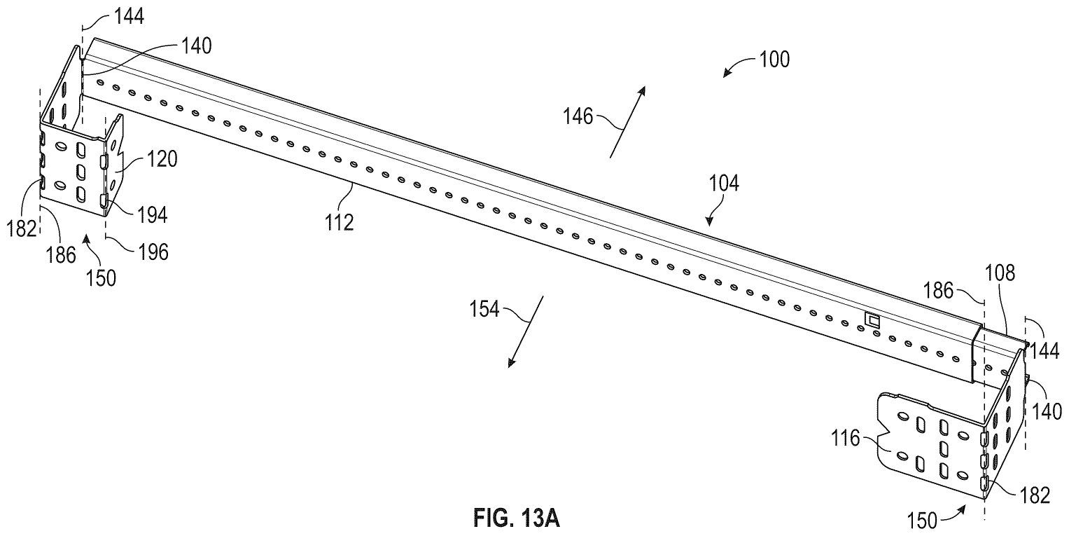

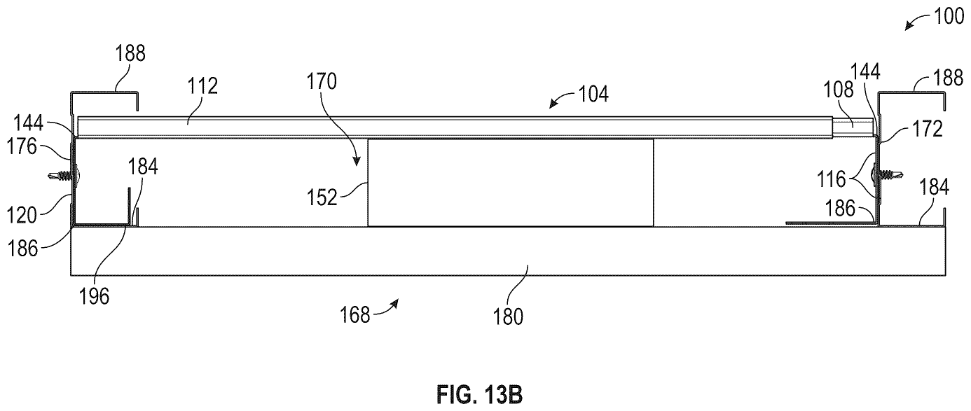

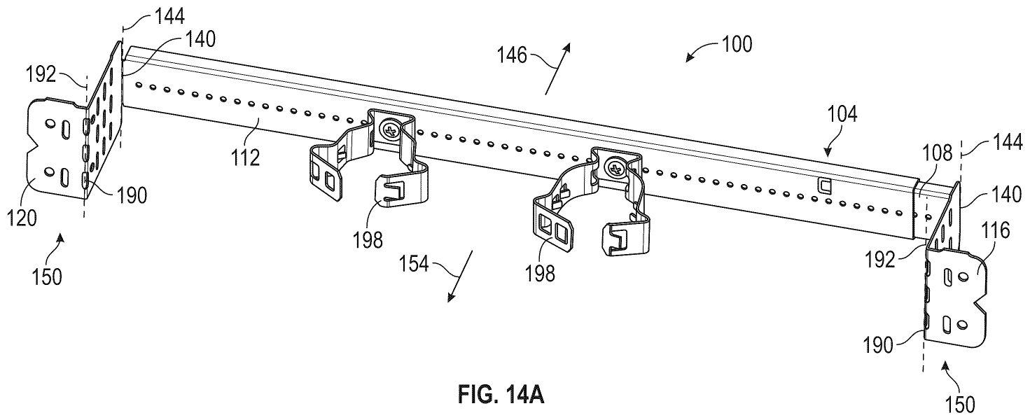

In some installations, the stud cavity 170 may be smaller, e.g., a distance from the support profile 104 and the drywall 180 may be shorter. In some installations, the flanges of the bracket may be bent to accommodate a smaller stud cavity 170 in a side installation. For example, as shown in FIG. 13A and FIG. 13B, the first and second flanges 116, 120 may be bent at bend lines 186 via bend features 182 inwardly to the stud cavity 170 (e.g., the free ends of the flanges, defined by portions of the flange past bend lines 186, extend inwardly to the stud cavity 170). Thus, as shown in FIG. 13B, the bracket 100 can be installed in a side installation within a smaller stud cavity 170. In some installations, due to the smaller size of the stud cavity 170, the flange 120 may additionally bend at bend lines 196 so that the flange 120 fits within the stud 176. In some installations, both the flange 120 and the flange 116 may be bent at bend line 196 so that the bracket is supported within the stud cavity 170. It should be noted that the bracket 100 in FIGS. 13A and 13B is substantially identical to the bracket 100 in FIG. 1, and discussed of the same should be applied to bracket 100 of FIGS. 13A and 13B.

As shown schematically in FIG. 13B, the electrical box 152 of FIG. 6A can be installed with the support bracket 100 in the side-face installation configuration shown in FIGS. 13A and 13B. Similarly, the electrical box 152 can be secured to the glider 148 and installed with the support bracket 100 in the side-face configuration shown in FIGS. 13A and 13B.

As discussed above, a support bracket 100 may be installed in a front installation in addition to the rear installation. For example, a support bracket may be configured so that end flanges are bent at bend features (and corresponding bend lines) to a front-face configuration so that the support bracket can be installed along a front of a stud.

In some installations, the support bracket 100 can be selectively bent to a front-face configuration, a side-face configuration, or a rear-face configuration (as also discussed above) to secure a FMOS or other electrical support to a prefabricated (or other) stud wall (e.g., similarly to the electrical box 152 as discussed above). In some examples, two instances of the support bracket 100 can thus be used to align the support profile 104 to provide support for the FMOS and a corresponding electrical box (e.g., the box 152) at substantially equal offsets relative to front or rear faces of a corresponding stud. Thus, for example, the support brackets 100 can be adaptably used to quickly and easily align electrical boxes and FMOSs in prefabricated wall assemblies.

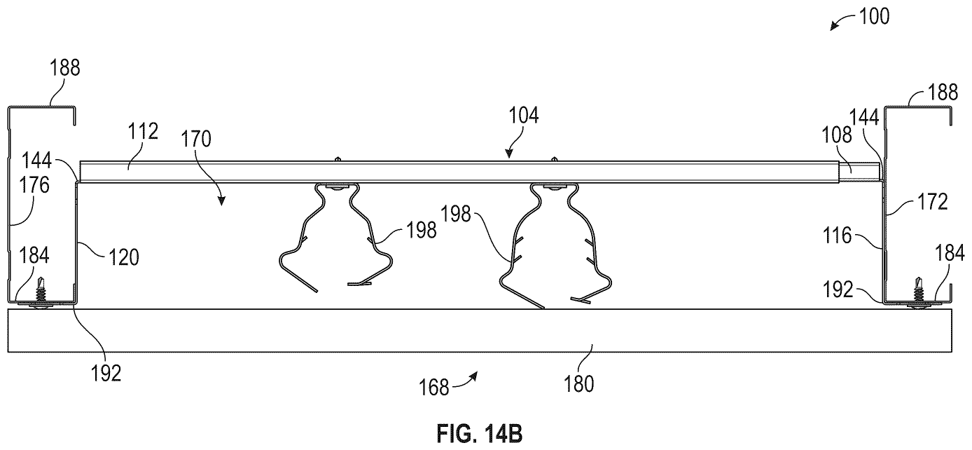

In particular, as shown in FIGS. 14A and 14B, the flanges 116, 120 may be bent at bend lines 144 via the bend features 140 so that the flanges 116, 120 extend along a direction substantially parallel to direction 154. Further, to be accommodated within the stud cavity 170, the flanges 116, 120 may be further bent along bend lines 192 via bend features 190 in a direction perpendicular to direction 154, to extend outwardly (e.g., in a direction that is opposite of the side-face configuration). In other words, as shown in FIG. 14B, the flanges 116, 120 may be bent to extend outwardly away from the stud cavity 170 (e.g., bent outwardly relatively to the stud cavity 170) so that the free ends of the flanges 116, 120 (e.g., ends of the flanges past the bend features 190) extend outwardly relative to the stud cavity 170). As shown in FIG. 14B, in particular, the first flange 116 can be installed on the front face 184 of the first stud 172 and the second flange 120 can be installed on the front face 184 of the second stud 176. Correspondingly, with the free ends of the flanges 116, 120 seated on front faces of the studs 172, 176, a distance between the bend features 140 and the bend features 190 may determine a distance between the support profile 104 and the drywall 180 of the prefabricated stud wall 168.

In some instances, a support bracket and corresponding support profile may provide a first means of support for an electrical component. For example, as discussed above, the bracket 100 may provide a first means of support for electrical components, so as electrical boxes (e.g., junction boxes, switches, outlets, etc.) and electrical supports (e.g., first means of support structures, conduit clips, cable clips, cable supports, conduit supports, etc.). As shown in FIG. 14A and FIG. 14B, the bracket 100 may include one or more supports 198 (e.g., conduit supports, cable supports, conduit clips, cable clips, or other FMOS devices for electrical components).

First means of support may be provided in various installations on the prefabricated stud walls 168. For example, as shown in FIG. 14A and FIG. 14B, the electrical supports 198 may be used with a front-side configuration of the bracket 100 to provide a first means of support. As further discussed below, however, electrical supports can be similarly installed with the support bracket in other configurations (e.g., side-face and rear-face configurations). Additionally, it should be noted that the electrical box 152 (see FIGS. 5A-11C) or other electrical components can be installed with the support bracket 100 in the front-face configuration shown in FIGS. 14A and 14B (e.g., directly or via the glider 148) or in other configurations (e.g., as variously illustrated in FIGS. 5A-11C). Correspondingly, separate instances of the support bracket 100 can be similarly bent and installed to support the electrical box 152 and the electrical supports 198 (e.g., in the front-face configuration as shown in FIGS. 14A and 14B)

In some installations, the electrical supports 198 of FIGS. 14A and 14B may include conduit/cable clips. Specifically, as illustrated the electrical supports 198 of FIGS. 14A and 14B may include clips for a ¾ inch conduit/cable or for a ¾ and 1 inch conduit/cable. In other installations, however, other electrical supports may be used, including straps for conduit/cable.

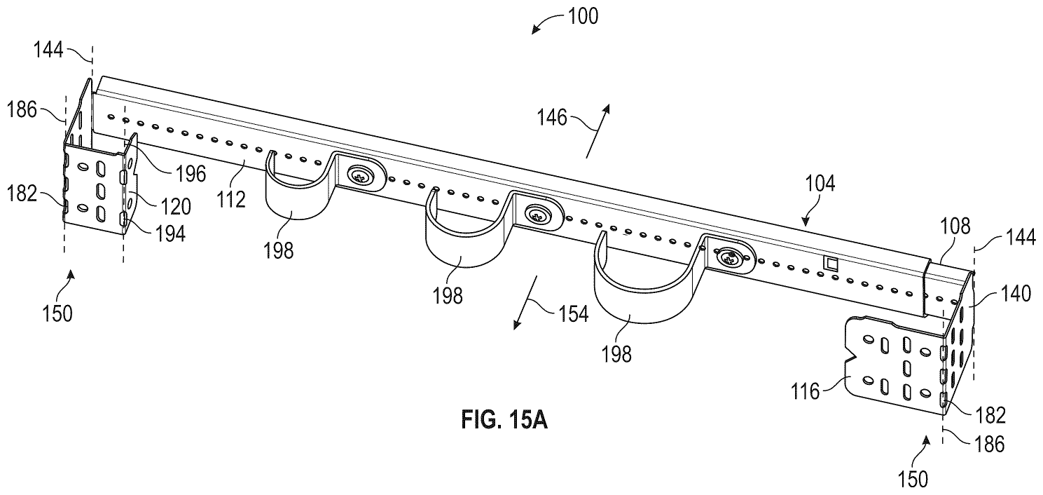

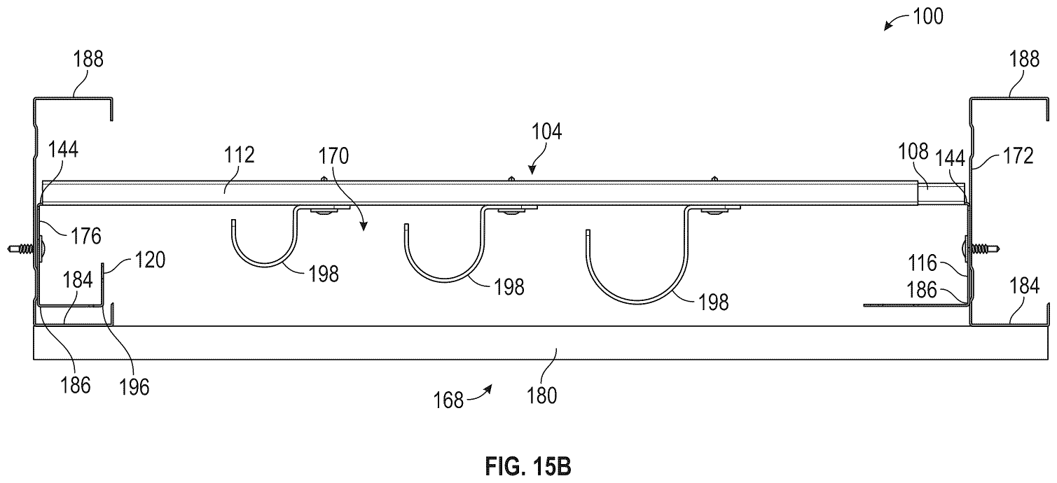

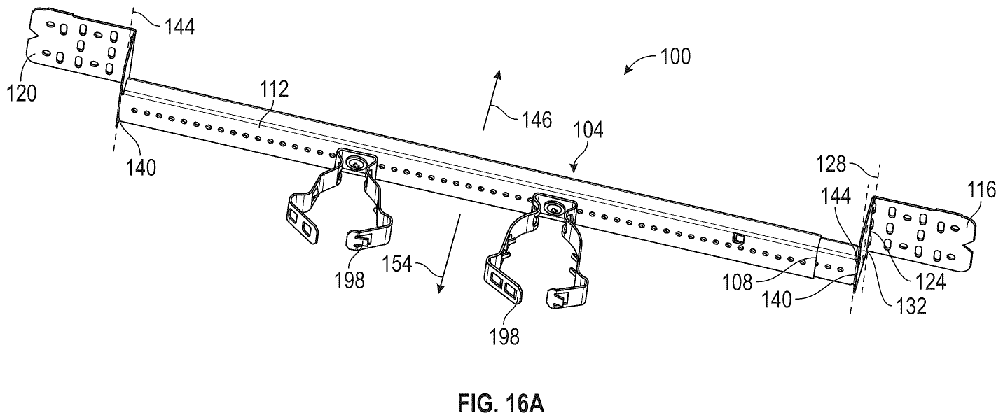

In some installations, including as shown in FIGS. 15A and 15B, the electrical supports 198 may be used with a side-face configuration of the bracket 100 (e.g., as shown and discussed in FIGS. 12A-13B), including to provide a first means of support as appropriate. In some examples, as shown in FIGS. 14A and 14B, the flanges 116, 120 may be bent to a side-face configuration as described for FIGS. 13A and 13B, but may be installed with a rearward offset of the flanges 116, 120 from rear sides of the front walls of the studs 172, 176. Or, other side-face configurations can be used in other installations.

In some embodiments, the electrical supports 198 of FIGS. 15A and 15B may include conduit/cable snaps. Specifically, the electrical supports 198 of FIGS. 15A and B may include snaps for a ¾ inch conduit/cable, for a 1 inch conduit/cable, or for a 1¼ inch conduit/cable. In other embodiments, however, other electrical supports may be used, including clips for conduit/cable.

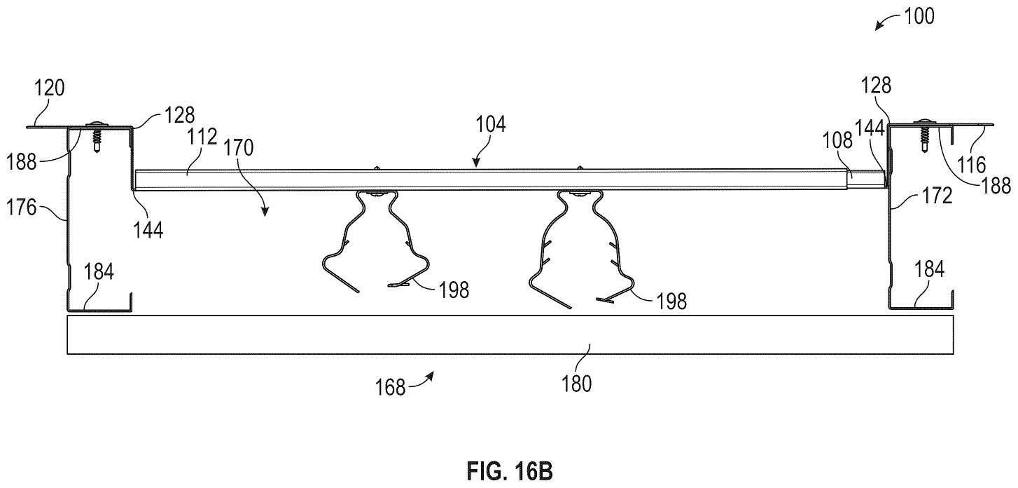

In some embodiments, as shown in FIGS. 16A and 16B, the electrical supports 198 may be used with a rear-face configuration of the bracket 100 with bends at the bend lines 128, 144 (e.g., as discussed relative to FIGS. 2A, 4A, 5A, 6A, 7A, 8, and 10A-10C), including to provide a first means of support. Alternatively, as discussed in FIGS. 2B, 4B, 5B, 6B, 7B, 9, and 11A-11C, the first and second flanges 116, 120 may be bent at the bend lines 136, 144 to an alternate rear-face configuration to secure the electrical supports 198 (e.g., as first means of support)

Thus, example of the disclosed technology can provide improved systems and methods for supporting electrical components on stud walls, including prefabricated stud walls. For example, as detailed above, end flanges of a support bracket can be selectively bent at predefined bend lines to support electrical assemblies on a variety of stud depths, including with the support bracket attached to rear faces of the studs of a prefabricated wall module in some installations, or selectively bent and attached in rear-face, side-face, or front-face configurations.

It is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

Also as used herein, unless otherwise limited or defined, “substantially parallel” indicates a direction that is within ±12 degrees of a reference direction (e.g., within ±6 degrees or ±3 degrees), inclusive. Similarly, unless otherwise limited or defined, “substantially perpendicular” similarly indicates a direction that is within ±12 degrees of perpendicular a reference direction (e.g., within ±6 degrees or ±3 degrees), inclusive. Correspondingly, “substantially vertical” indicates a direction that is substantially parallel to the vertical direction, as defined relative to the reference system (e.g., a local direction of gravity, by default), with a similarly derived meaning for “substantially horizontal” (relative to the horizontal direction). Discussion of directions “transverse” to a reference direction indicate directions that are not substantially parallel to the reference direction. Correspondingly, some transverse directions may be perpendicular or substantially perpendicular to the relevant reference direction.

Also as used herein, unless otherwise limited or defined, “or” indicates a non-exclusive list of components or operations that can be present in any variety of combinations, rather than an exclusive list of components that can be present only as alternatives to each other. For example, a list of “A, B, or C” indicates options of: A; B; C; A and B; A and C; B and C; and A, B, and C. Correspondingly, the term “or” as used herein is intended to indicate exclusive alternatives only when preceded by terms of exclusivity, such as “only one of,” or “exactly one of.” For example, a list of “only one of A, B, or C” indicates options of: A, but not B and C; B, but not A and C; and C, but not A and B. In contrast, a list preceded by “one or more” (and variations thereon) and including “or” to separate listed elements indicates options of one or more of any or all of the listed elements. For example, the phrases “one or more of A, B, or C” and “at least one of A, B, or C” indicate options of: one or more A; one or more B; one or more C; one or more A and one or more B; one or more B and one or more C; one or more A and one or more C; and one or more A, one or more B, and one or more C. Similarly, a list preceded by “a plurality of” (and variations thereon) and including “or” to separate listed elements indicates options of one or more of each of multiple of the listed elements. For example, the phrases “a plurality of A, B, or C” and “two or more of A, B, or C” indicate options of: one or more A and one or more B; one or more B and one or more C; one or more A and one or more C; and one or more A, one or more B, and one or more C.

Also as used herein, unless otherwise limited or defined, “integral” and derivatives thereof (e.g., “integrally”) describe elements that are manufactured as a single piece without fasteners, adhesive, or the like to secure separate components together. For example, an element that is stamped, cast, or otherwise molded as a single-piece component from a single piece of sheet metal or using a single mold, without rivets, screws, other fasteners, or adhesive to hold separately formed pieces together is an integral (and integrally formed) element. In contrast, an element formed from multiple pieces that are separately formed initially then later connected together, is not an integral (or integrally formed) element.

Also as used herein, unless otherwise limited or specified, “substantially identical” refers to two or more components or systems that are manufactured according to the same process and specification, with variation between the components or systems that are within the limitations of acceptable tolerances for the relevant process or specification. For example, two components can be considered to be substantially identical if the components are manufactured according to the same standardized manufacturing steps, with the same materials, and within the same acceptable dimensional tolerances (e.g., as specified for a particular process or product).

Also as used herein, in the context of a stud cavity, “inwardly” and “outwardly” (and the like) refer to directions that extend, respectively, laterally towards the lateral center of the stud cavity or laterally away from the lateral center of the stud cavity. In this regard, for example, a flange that is bend outwardly, in the installed orientation, extends from the bend laterally away from a lateral center of the stud cavity (e.g., to extend along a front or rear face of a stud away from the corresponding stud cavity). Similarly, a flange that is bent inwardly, in the installed orientation, extends from the bend laterally toward a lateral center of the stud cavity (e.g., to extend from a side face of stud into the corresponding stud cavity).

Unless otherwise specified or limited, the terms “about” and “approximately,” as used herein with respect to a reference value, refer to variations from the reference value of ±20% or less (e.g., ±15, ±10%, ±5%, etc.), inclusive of the endpoints of the range. Similarly, as used herein with respect to a reference value, the term “substantially equal” (and the like) refers to variations from the reference value of ±5% or less (e.g., ±2%, ±1%, ±0.5%) inclusive.

Unless otherwise specifically indicated, ordinal numbers are used herein for convenience of reference, based generally on the order in which particular components are presented in the relevant part of the disclosure. In this regard, for example, designations such as “first,” “second,” etc., generally indicate only the order in which a thus-labeled component is introduced for discussion and generally do not indicate or require a particular spatial, functional, temporal, or structural primacy or order.

In some implementations, devices or systems disclosed herein can be utilized, manufactured, installed, etc. using methods embodying aspects of the disclosed technology. Correspondingly, any description herein of particular features, capabilities, or intended purposes of a device or system should be considered to disclose, as examples of the disclosed technology a method of using such devices for the intended purposes, a method of otherwise implementing such capabilities, a method of manufacturing relevant components of such a device or system (or the device or system as a whole), and a method of installing disclosed (or otherwise known) components to support such purposes or capabilities. Similarly, unless otherwise indicated or limited, discussion herein of any method of manufacturing or using for a particular device or system, including installing the device or system, should be understood to disclose, as examples of the disclosed technology, the utilized features and implemented capabilities of such device or system.

Some methods of the disclosed technology may be presented above or below with operations listed in a particular order. Unless otherwise required or specified, the operations of such methods can be implemented in different orders, in parallel, or as selected sub-sets of one or more individual operations (e.g., with a particular listed operation being implemented alone, rather than in combination with others).

The previous description of the disclosed examples is provided to enable any person skilled in the art to make or use the disclosure. Various modifications to these examples will be readily apparent to those skilled in the art, and the generic principles defined herein may be applied to other examples without departing from the spirit or scope of the disclosed technology. Thus, the disclosure is not intended to be limited to the examples shown herein but is to be accorded the widest scope consistent with the principles and novel features disclosed herein.

We claim:

1. A method of supporting an electrical system, the method comprising:
providing a stud wall that includes a first stud, a second stud, and drywall secured to front faces of the first and second studs;
selectively bending first and second end flanges of a support bracket at first preformed bend lines on the first and second end flanges or at second preformed bend lines on the first and second end flanges;
securing an electrical component to a support profile of the support bracket that extends between the first and second end flanges; and
after securing the electrical component to the support profile, securing the first and second end flanges to rear faces of the first and second studs so that the first and second end flanges extend along interior sides of the first and second studs to align the support profile to support the electrical component:
at a first offset from the rear faces of the first and second studs, with the first and second end flanges bent at the first preformed bend lines; or
at a second offset from the rear faces of the first and second studs, with the first and second end flanges bent at the second preformed bend lines, the second offset being smaller than the first offset.

2. The method of claim 1, wherein the electrical component is secured at a front side of the support profile; and
wherein the first and second end flanges are bent rearward away from the front side of the support profile.

3. The method of claim 1, wherein the first and second end flanges further include:
third preformed bend lines configured to provide a side-face configuration to secure the support bracket to side walls of the first and second studs; and
fourth preformed bend lines configured to provide a front-face configuration to secure the support bracket to the front faces of the first and second studs.

4. The method of claim 1, wherein the electrical component includes a conductor support.

5. The method of claim 1, wherein the electrical component includes an electrical box.

6. The method of claim 5, further comprising:
selectively bending first and second end flanges of a second support bracket at first preformed bend lines on the first and second end flanges of the second support bracket or at second preformed bend lines on the first and second end flanges of the second support bracket;
securing a conductor support to a support profile of the second support bracket that extends between the first and second end flanges of the second support bracket; and
after securing the conductor support to the support profile of the second support bracket, securing the first and second end flanges of the second support bracket to the rear faces of the first and second studs so that the conductor support is aligned above the electrical box:
at a third offset from the rear faces of the first and second studs, with the first and second end flanges of the second support bracket bent at the first preformed bend lines; or
at a fourth offset from the rear faces of the first and second studs, with the first and second end flanges of the second support bracket bent at the second preformed bend lines, the fourth offset being smaller than the third offset.

7. The method of claim 6, wherein the third offset is substantially equal to the first offset and the fourth offset is substantially equal to the second offset.

8. The method of claim 5, further comprising:
securing a mud ring to a front side of the electrical box with screws; and
wherein, with the first and second studs being 3⅝ inch studs, the first offset aligns the electrical box with the mud ring extending forward of a rear face of the drywall and with the screws flush with or rearward of the rear face of the drywall.

9. The method of claim 5, further comprising:
securing a mud ring to a front side of the electrical box with screws; and
wherein, with the first and second studs being 2½ inch studs, the second offset aligns the electrical box with the mud ring extending forward of the rear face of the drywall and with the screws flush with or rearward of the rear face of the drywall.

10. A method of supporting an electrical system, the method comprising:
providing a stud wall that includes a first stud and a second stud that form a stud cavity, each of the first stud and the second stud having a front face configured to secure drywall to the stud wall;
selectively bending first and second end flanges of a support bracket at selective corresponding bend features to form one of a front-face configuration, a rear-face configuration, or a side-face configuration;
securing an electrical component to a support profile of the support bracket that extends between the first and second end flanges; and
after securing the electrical component to the support profile, securing the first and second end flanges to the first and second studs so that the support profile is aligned to support the electrical component with:
a front of the electrical component at a first offset rearward of the front faces of the first and second studs; and
selectively, one of:
the first and second end flanges secured in the front-face configuration to the front faces the first and second studs;
the first and second end flanges secured in the rear-face configuration to rear faces of the first and second studs; or
the first and second end flanges secured in the side-face configuration to side faces of the first and second studs.

11. The method of claim 10, wherein bending the first and second end flanges to form the front-face configuration includes bending free ends of the first and second end flanges outward relative to the stud cavity; and
wherein bending the first and second end flanges to form the side-face configuration includes bending the free ends of the first and second end flanges inward relative to the stud cavity.

12. The method of claim 11, wherein bending the first and second end flanges to form the front-face configuration includes bending the free ends outward at first bend features; and
bending the first and second end flanges to form the side-face configuration includes bending the free ends inward at the first bend features.

13. The method of claim 12, wherein with the first and second end flanges in the side-face configuration, securing the first and second end flanges to the first and second studs seats the first end flange on a front wall of the first stud that includes the front face of the first stud.

14. The method of claim 10, wherein each of the first end flange and the second end flange includes, in order, moving away from the support profile: a first bend feature, a second bend feature, a third bend feature; and
wherein selectively bending the first and second end flanges to the rear-face configuration includes selectively bending the first and second end flanges at one of: the first bend features, or the second bend features.

15. The method of claim 14, wherein selectively bending the first and second end flanges to the front-face configuration includes bending the first and second end flanges at the third bend features.

16. The method of claim 15, wherein selectively bending the first and second end flanges to the front-face configuration includes bending the first and second end flanges outwardly at the third bend features, and selectively bending the first and second end flanges to the side-face configuration includes bending the first and second end flanges inwardly at the third bend features.

17. The method of claim 15, wherein each of the first end flange and the second end flange further includes a fourth bend feature, between the corresponding first bend feature and the support profile; and
wherein selectively bending the first and second end flanges to the rear-face configuration includes selectively bending the first and second end flanges to extend rearward at the fourth bend features and selectively bending the first and second end flanges to the front-face configuration includes bending the first and second end flanges to extend forward at the fourth bend features.

18. A support bracket to support an electrical system, the support bracket comprising:
a first end flange securable to a first stud;
a second end flange securable to a second stud that is configured to form a stud cavity with the first stud in a stud wall; and
a support profile extending between the first and second end flanges and configured to secure an electrical component;
each of the first end flange and the second end flange including, respectively, bend features configured to be selectively bent to form any of a front-face configuration, a rear-face configuration, and a side-face configuration;
the first and second end flanges being securable to the first and second studs so that the support profile is aligned to support the electrical component with a front of the electrical component at a first offset rearward of the front faces of the first and second studs and with, selectively, one of:
the first and second end flanges secured in the front-face configuration to the front faces the first and second studs;
the first and second end flanges secured in the rear-face configuration to rear faces of the first and second studs; or
the first and second end flanges secured in the side-face configuration to side faces of the first and second studs.

19. The support bracket of claim 18, wherein the bend features for each of the first and second end flanges include one or more first bend features that define a first bend line, and one or more second bend features that define a second bend line;
the first and second end flanges being bendable rearward relative to the stud cavity in the rear-face configuration so that the support profile supports the electrical component at the first offset rearward of the front faces of the first and second studs, with the first and second end flanges being selectively bendable:
at the first bend lines to engage the rear faces of the first and second studs and extend along interior sides of the first and second studs, to align the support profile to support the electrical component at a first rear face offset from the rear faces of the first and second studs; and
at the second bend lines to engage the rear faces of the first and second studs and extend along the interior sides of the first and second studs, to align the support profile to support the electrical component at a second rear face offset from the rear faces of the first and second studs that is smaller than the first rear face offset.

20. The support bracket of claim 18, wherein the bend features for each of the first end flange and the second end flange include one or more additional bend features that define one or more additional bend lines; and
wherein the first and second end flanges are selectively bendable at the one or more additional bend lines:
forward relative to the stud cavity to the front-face configuration and the side-face configuration;
outwardly relative to the stud cavity to engage the front faces of the first and second studs in the front-face configuration, and
inwardly relative to the stud cavity to engage the side faces of the first and second studs in the side-face configuration.
